(19) United States
(12) Patent Application Publication
(10) Pub. No.: US 2002/0024126 A1
(43) Pub. Date: Feb. 28, 2002

(54) Integrated circuit, casting mold for producing an integrated module, method of producing an integrated circuit, and method of testing an integrated circuit

(76) Inventors: Christian Hauser, Regensburg (DE); Ulrich Vidal, Landshut (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/940,089

(22) Filed: Aug. 27, 2001

Related U.S. Application Data
(63) Continuation of application No. PCT/DE00/00483, filed on Feb. 21, 2000.

(30) Foreign Application Priority Data
Feb. 25, 1999 (DE) 199 08 186.7

(51) Int. Cl. H01L 23/02

(52) U.S. Cl. 257/678

(57) ABSTRACT

A first casting mold region and a second casting mold region are brought together, with the result that a cavity, which is provided for receiving a leadframe and can be filled with a plastic molding compound, is formed. The first and second casting mold regions are brought together in such a way that at least a first contact region of the first casting mold region bears against a second contact region of the second casting mold region. The plastic package of the integrated circuit produced in this way has a smooth, burr-free surface, at least in the region of a centering portion. An integrated circuit having a lead frame and a plastic package and a test method for testing the integrated circuit are also provided.

### CROSS-REFERENCE TO RELATED APPLICATION

This application is a continuation of copending International Application No. PCT/DE00/00483, filed Feb. 21, 2000, which designated the United States.

### BACKGROUND OF THE INVENTION

1. Field of the Invention

The invention relates to a method of producing an integrated circuit which has a plastic package and a metallic leadframe. The invention also relates to a casting mold for producing an integrated circuit and to an integrated circuit itself. The invention further relates to a method of functionally testing an integrated circuit.

It is known in the prior art to produce integrated circuits with a plastic package and to subject them to an electrical functional test after production. In such a functional test, an integrated circuit is introduced into a test socket and is electrically contacted and tested, cf. for example International Publication No. WO 99/52149.

In the case of the integrated circuits known from the prior art, it is often the case that an electrical functional test produces negative results even though the integrated circuit is functional. This leads to an increased number of rejects.

Japanese Patent Application No. JP 01-0268036 discloses a casting mold for producing an integrated module in which trapezoidal plastic bodies are provided between the leads of a leadframe which are thinner by several μ to 20 μ than the respectively neighboring leads. After encapsulation, the thin burrs or flashes produced by this are easily removable. The two halves of the casting mold do not lie directly against each other and the burrs are not avoided

2. Summary of the Invention

It is accordingly an object of the invention to provide an integrated circuit which overcomes the above-mentioned disadvantages of the heretofore-known integrated circuits of this general type and which causes a reduced number of rejects during its production. It is also an object of the invention to provide a casting mold for producing an integrated module with a plastic package and a method of producing an integrated circuit by which a reduced number of rejects is made possible. Finally, an improved functional testing method is to be provided.

With the foregoing and other objects in view there is provided, in accordance with the invention, a casting mold configuration for producing an integrated module with a plastic package, including:

a casting mold divided into a first casting mold region and a second casting mold region;

the first casting mold region being formed with a first cavity region, the second casting mold region being formed with a second cavity region;

the first cavity region and the second cavity region forming a cavity when the first casting mold region and the second casting mold region are in an assembled state, the cavity being configured to receive a metallic leadframe and to be filled with a plastic molding compound;

the casting mold having an edge region configured to form a centering edge on a plastic package;

the first cavity region having a first contact region in the edge region of the casting mold, the second cavity region having a second contact region in the edge region of the casting mold; and

the first contact region bearing against the second contact region when the first casting mold region and the second casting mold region are in the assembled state.

A casting mold according to the invention is divided into a first casting mold region with a first cavity region and into at least a second casting mold region with a second cavity region. In the assembled state of the first casting mold region and second casting mold region, the first cavity region and the second cavity region form a cavity for receiving a metallic leadframe. To form the plastic package, the cavity is filled with plastic molding compound with the leadframe inserted. According to the invention, the casting mold has at least one edge region for forming a centering edge. The edge region has in the first cavity region at least a first contact region, which in the assembled state of the first casting mold region and second casting mold region with the leadframe introduced in between bears against a second contact region, provided in the second cavity region.

According to an idea underlying the invention, the production of a burr-free or flash-free plastic package is made possible by the casting mold configured according to the invention. This is because, specifically in the edge region, the plastic package is then molded exclusively by the casting mold, which can be configured in a simple way such that there is no burr in the plastic package.

It has indeed been found that the integrated circuits incorrectly identified as non-functional produce inadequate results in the functional test on account of the presence of an undesired burr on the plastic package. In the functional test, the integrated circuits are initially introduced into a test socket and then electrically contacted. Particularly in 0 the case of very small leadframe dimensions, exact centering of the integrated circuit in the socket is required. The alignment of the integrated circuit is carried out through the use of stops, which use the corners of the integrated circuit as a basis. In the case of the configuration of the casting mold according to the invention, it has been found that integrated circuits with plastic packages which can be centered particularly accurately in a test socket can be produced, and that this is so even when there is an offset between the package and the leadframe on account of the production process.

According to another feature of the invention, the casting mold has several edge regions that are configured to form a centering edge on a plastic package.

According to yet another feature of the invention, the first contact region has a first contact surface, the second contact region has a second contact surface, and the first contact surface rests on the second contact surface when the first casting mold region and the second casting mold region are in the assembled state.

According to a further feature of the invention, the first contact surface has a first side edge, the second contact surface has a second side edge, and the first side edge coincides with the second side edge when the first casting mold region and the second casting mold region are in the assembled state.

According to another feature of the invention, the first contact surface lies substantially flat on the second contact surface when the first casting mold region and the second casting mold region are in the assembled state.

According to another feature of the invention, the casting mold has a rounded-off corner, and the edge region of the casting mold is disposed at the rounded-off corner.

With the objects of the invention in view there is also provided, a method of producing an integrated circuit with a plastic package, the method includes the steps of:

providing a casting mold divided into a first casting mold region formed with a first cavity region and into at least a second casting mold region formed with a second cavity region;

inserting a metallic leadframe between the first casting mold region and the second casting mold region; and

bringing the first casting mold region and second casting mold region together such that the first cavity region and the second cavity region form a cavity between the first casting mold region and the second casting mold region for receiving the metallic leadframe such that a first contact region provided in the first cavity region bears against a second contact region provided in the second cavity region, and such that the cavity can be filled with a plastic molding compound.

In the method according to the invention, firstly a casting mold which is divided into a first casting mold region with a first cavity region and at least a second casting mold region with a second cavity region is provided. Then, a metallic leadframe is inserted between the first casting mold region and the second casting mold region. After that, the first casting mold region is brought together with the second casting mold region in such a way that, between the first casting mold region and the second casting mold region, the first cavity region and the second cavity region form a cavity for receiving the metallic leadframe. The cavity formed in this way is intended for receiving a plastic molding compound. According to the invention, the bringing together of the first casting mold region and second casting mold region takes place in such a way that at least a first contact region in the first casting mold region bears against a second contact region provided in the second cavity region. In the method according to the invention, unlike in the methods known in the prior art, the cavity in the region between the first casting mold region and second casting mold region is not sealed off just via a region of the leadframe. Rather, it is provided that the first casting mold region and the second casting mold region touch the leadframe only partially, from the upper side and from the underside respectively. In addition, the first casting mold region and the second casting mold region touch each other directly, a burr-free surface of the plastic package produced by the casting mold being ensured specifically at these points of contact at which a first contact region in the first cavity region bears against a second contact region in the second cavity region.

With the objects of the invention in view there is also provided, an integrated circuit, including: a metallic leadframe defining a given main plane, the metallic leadframe extending substantially in the given main plane; and

a plastic package having at least one centering portion disposed substantially at the given main plane, the plastic package covering the leadframe substantially completely at least at the at least one centering portion such that the plastic package forms a smooth, burr-free surface on the plastic package.

According to another feature of the invention, the plastic package has a corner region, and the smooth, burr-free surface on the plastic package is provided at the corner region.

The integrated circuit of the invention has a metallic leadframe and a plastic package, the plastic package having at least one centering portion, which may be provided in the main plane of extent of the leadframe. In the case of the integrated circuit according to the invention, the plastic package covers the leadframe essentially completely, at least in the region of the centering portion, with the result that a smooth, burr-free surface is formed on the plastic package.

According to the invention, the casting mold may also have a plurality of edge regions which serve for producing a plurality of centering portions on the package of the integrated circuit. In this case, the first contact region in the first cavity region may have a first contact surface, which in the assembled state of the first casting mold region and second casting mold region rests on a second contact surface, provided on the second contact region. In the assembled state of the first casting mold region and second casting mold region, the two contact surfaces preferably lie in a parting plane of the casting mold, with the result that undercuts in the casting mold can be avoided. The provision of a first contact surface and a second contact surface allows the production of a burr-free plastic package specifically in the region of the centering portion. In this case, at least one side edge of the first contact surface coincides in the assembled state of the first casting mold region and second casting mold region with a side edge of the second contact surface. In this way, a plastic package which has a centering portion which is obtained from the region of the side edges of the contact surfaces can be produced.

In tests with the casting mold according to the invention, it has been found that the plastic package of an integrated circuit often has a burr when a leadframe is held between a first casting mold region and second casting mold region during the production of the plastic package, with the result that the cavity produced is sealed off by the pressing of the casting mold regions against the leadframe. The size of the burr produced is determined by the leadframe opening and by the pressing operation. According to the invention, longitudinal centering of the integrated circuit is provided in the functional test, to be precise at those locations of the plastic package which are produced in such a way that they are free from burrs or flashes. For this purpose, a modified leadframe in comparison with the leadframes known from the prior art is used, the modified leadframe having at certain locations recesses for formations or given shapes of the casting mold regions of the casting mold used for producing the plastic package. The sealing off of the cavity is then no longer accomplished entirely via the leadframe, but in part-regions by pressing formations of the casting mold regions on to one another. In these part-regions, no burr is produced on the plastic package. The size of the package to be produced preferably corresponds exactly to the size and tolerances of the cavity of the casting mold, taking into account the shrinkage caused by the method. This produces a precise outer contour, which may be used for the centering in a test socket.

With the objects of the invention in view there is also provided, a method of functionally testing an integrated circuit with a plastic package, the method includes the steps of:

providing an integrated circuit having a metallic leadframe and a plastic package, the metallic leadframe extending substantially in a given main plane, the plastic package having at least one centering portion disposed substantially at the given main plane, the plastic package covering the leadframe substantially completely at least at the at least one centering portion such that the plastic package forms a smooth, burr-free surface on the plastic package; and

inserting the integrated circuit into a test mount such that the at least one centering portion of the plastic package bears against a centering stop in the test mount.

With the objects of the invention in view there is further provided, a method of functionally testing an integrated circuit with a plastic package, the method includes the steps of:

providing an integrated circuit having a metallic leadframe and a plastic package, the integrated circuit being produced by using a casting mold divided into a first casting mold region formed with a first cavity region and into at least a second casting mold region formed with a second cavity region, by inserting the metallic leadframe between the first casting mold region and the second casting mold region, by bringing the first casting mold region and second casting mold region together such that the first cavity region and the second cavity region form a cavity between the first casting mold region and the second casting mold region for receiving the metallic leadframe such that a first contact region provided in the first cavity region bears against a second contact region provided in the second cavity region, and by filling the cavity with a plastic molding compound; and

inserting the integrated circuit into a test mount such that at least one centering portion formed on the plastic package bears against a centering stop in the test mount.

Other features which are considered as characteristic for the invention are set forth in the appended claims.

Although the invention is illustrated and described herein as embodied in an integrated circuit and a method of producing and testing an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic plan view of an integrated circuit according to the invention with a plastic package;

FIG. 2 is a diagrammatic plan view of an enlarged detail of the integrated circuit of FIG. 1;

FIG. 3 is a partial, diagrammatic cross-sectional view of a casting mold according to the invention during the production of the integrated circuit of FIG. 1, along a first sectional plane A-A;

FIG. 4 is a diagrammatic cross-sectional view of an enlarged detail of FIG. 3;

FIG. 5 is partial, diagrammatic cross-sectional view of the casting mold of FIG. 3, along a second sectional plane B-B; and

FIG. 6 is a diagrammatic cross-sectional view of an enlarged detail of FIG. 5.

### DESCRIPTION OF THE PREFERRED EMBODIMENTS

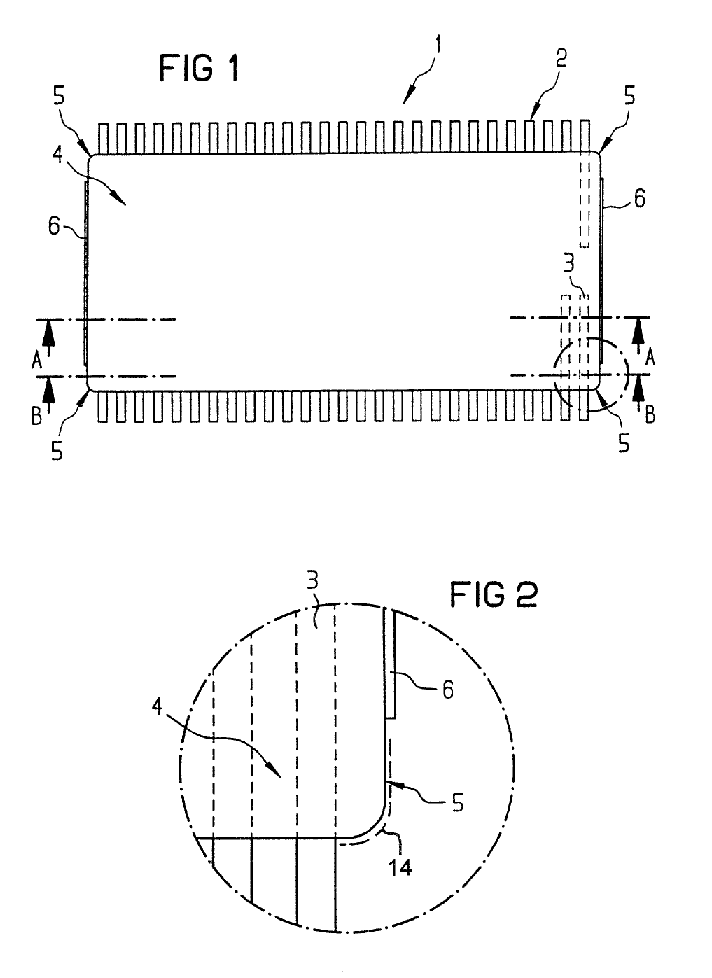

Referring now to the figures of the drawings in detail and first, particularly, to FIG. 1 thereof, there is shown a plan view of an integrated circuit 1 according to the invention. The integrated circuit 1 has a metallic leadframe 2 with conductor tracks 3, only one of which is designated by a reference numeral in this view. The leadframe 2 is encapsulated by a plastic package 4, which has in plan view an essentially rectangular outline with rounded-off corners. In this case, each corner is formed as a burr-free centering portion 5, while regions neighboring the centering portions 5 on the peripheral side wall of the plastic package 4 have a package burr 6.

FIG. 2 shows an enlarged detail from FIG. 1. As can be seen particularly well in this view, the package burr 6 is interrupted at the transition point between the package burr or housing burr 6 and centering portion 5 in such a way that the side surface of the plastic package 4 in the centering portion 5 is formed such that it is smooth and free from burrs. During a functional testing of the integrated circuit 1, the integrated circuit 1 is inserted into a test mount such that the centering portion 5 formed on the plastic package 4 bears against a centering stop 14 of the test mount which is only schematically shown as a dashed line in FIG. 2.

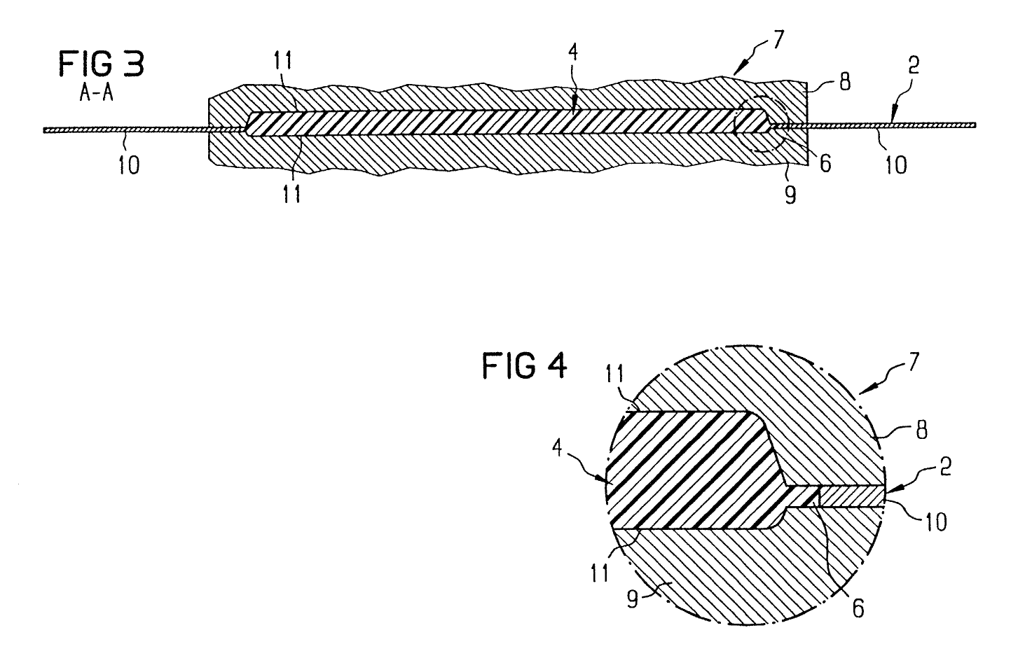

FIG. 3 shows a cross section along a sectional plane A-A through a casting mold according to the invention at one point in time during the production of the circuit 1 according to the invention. The casting mold 7 is divided into a first casting mold region 8 and a second casting mold region 9, between which the leadframe 2 is clamped in the assembled state of the first casting mold region 8 and second casting mold region 9. Shown in this view are handling regions 10 of the leadframe 2, which are clamped between the first casting mold region 8 and the second casting mold region 9 and which seal off a cavity 11, formed in the casting mold 7, against the escape of plastic molding compound to the outer side of the casting mold 7.

FIG. 4 shows an enlarged detail of the configuration shown in FIG. 3, on the basis of which the production of the package burr 6 from FIG. 1 and FIG. 2 can be illustrated. As can be seen particularly well in FIG. 4, the handling regions 10 of the leadframe 2 clamped in between the first casting mold region 8 and the second casting mold region 9 are provided in such a way that an additional hollow space is produced in a transitional region of the cavity 11 between the first casting mold region 8 and the second casting mold region 9 and is filled by the plastic molding compound used for producing the plastic package 4.

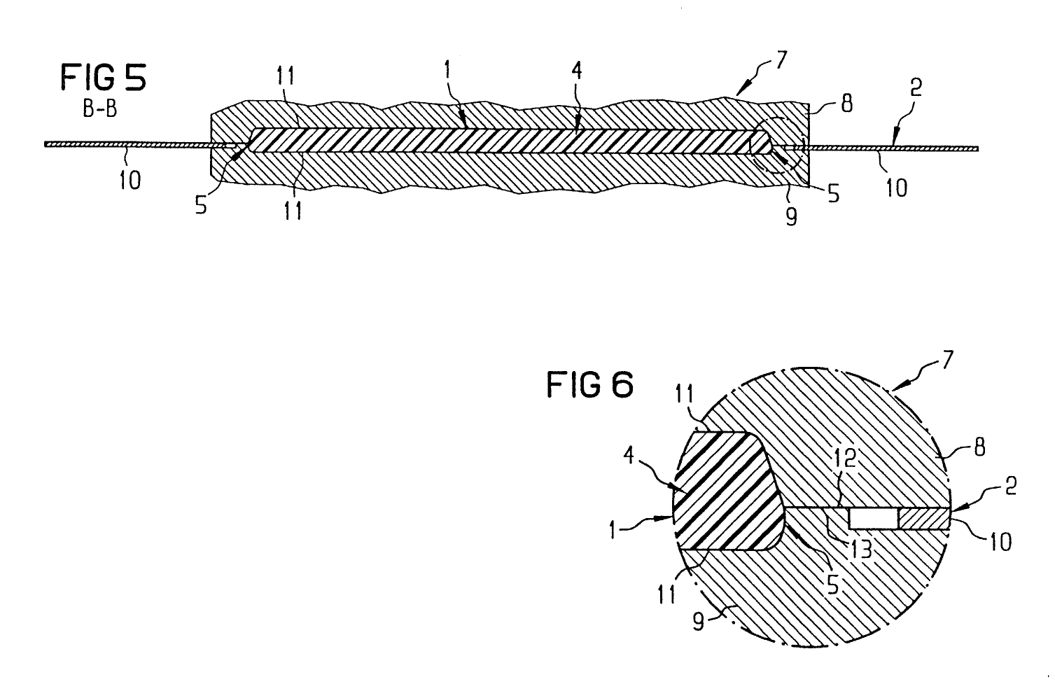

FIG. 5 shows a cross section through the casting mold 7 of FIG. 3, to be precise along a sectional plane B-B through the integrated circuit 1 of FIG. 1.

FIG. 5 illustrates the production of the plastic package 4 in the region of a centering portion 5, which is formed without package burr 6. As can be seen in the detail of the casting mold 7 shown in FIG. 6 and enlarged in comparison with FIG. 5, the first casting mold region 8 has in the region of the centering portion 5 a first contact region 12, which in the assembled state of the first casting mold region 8 and second casting mold region 9 lies flat on a second contact region 13 formed on the second casting mold region 9. The inner wall of the cavity in the region of the first contact region 12 and in the region of the second contact region 13 has smooth transitions, with the result that the plastic package 4 formed at this location has a smooth and essentially burr-free surface. The first contact region 12 and the second contact region 13 preferably lie in the parting plane of the casting mold 7, with the result that no undercutting occurs during the production of the plastic package 4.

We claim:

1. A casting mold configuration for producing an integrated module with a plastic package, comprising:
a casting mold divided into a first casting mold region and a second casting mold region;
said first casting mold region being formed with a first cavity region, said second casting mold region being formed with a second cavity region;
said first cavity region and said second cavity region forming a cavity when said first casting mold region and said second casting mold region are in an assembled state, said cavity being configured to receive a metallic leadframe and to be filled with a plastic molding compound;
said casting mold having an edge region configured to form a centering edge on a plastic package;
said first cavity region having a first contact region in said edge region of said casting mold, said second cavity region having a second contact region in said edge region of said casting mold; and
said first contact region bearing against said second contact region when said first casting mold region and said second casting mold region are in the assembled state.

2. The casting mold configuration according to claim 1, wherein said casting mold has further edge regions.

3. The casting mold configuration according to claim 1, wherein:
said first contact region has a first contact surface, said second contact region has a second contact surface; and
said first contact surface rests on said second contact surface when said first casting mold region and said second casting mold region are in the assembled state.

4. The casting mold configuration according to claim 3, wherein:
said first contact surface has a first side edge, said second contact surface has a second side edge; and
said first side edge coincides with said second side edge when said first casting mold region and said second casting mold region are in the assembled state.

5. The casting mold configuration according to claim 3, wherein said first contact surface lies substantially flat on said second contact surface when said first casting mold region and said second casting mold region are in the assembled state.

6. The casting mold configuration according to claim 1, wherein:
said casting mold has a rounded-off corner; and
said edge region of said casting mold is disposed at said rounded-off corner.

7. A method of producing an integrated circuit with a plastic package, the method which comprises:
providing a casting mold divided into a first casting mold region formed with a first cavity region and into at least a second casting mold region formed with a second cavity region;
inserting a metallic leadframe between the first casting mold region and the second casting mold region; and
bringing the first casting mold region and second casting mold region together such that the first cavity region and the second cavity region form a cavity between the first casting mold region and the second casting mold region for receiving the metallic leadframe such that a first contact region provided in the first cavity region bears against a second contact region provided in the second cavity region, and such that the cavity can be filled with a plastic molding compound.

8. An integrated circuit, comprising:
a metallic leadframe defining a given main plane, said metallic leadframe extending substantially in the given main plane; and
a plastic package having at least one centering portion disposed substantially at the given main plane, said plastic package covering said leadframe substantially completely at least at said at least one centering portion such that said plastic package forms a smooth, burr-free surface on said plastic package.

9. The integrated circuit according to claims, wherein:
said plastic package has a corner region; and
said smooth, burr-free surface on said plastic package is provided at said corner region.

10. A method of functionally testing an integrated circuit with a plastic package, the method which comprises:
providing an integrated circuit having a metallic leadframe and a plastic package, the metallic leadframe extending substantially in a given main plane, the plastic package having at least one centering portion disposed substantially at the given main plane, the plastic package covering the leadframe substantially completely at least at the at least one centering portion such that the plastic package forms a smooth, burr-free surface on the plastic package; and
inserting the integrated circuit into a test mount such that the at least one centering portion of the plastic package bears against a centering stop in the test mount.

11. A method of functionally testing an integrated circuit with a plastic package, the method which comprises:
providing an integrated circuit having a metallic leadframe and a plastic package, the integrated circuit being produced by using a casting mold divided into a first casting mold region formed with a first cavity region and into at least a second casting mold region formed with a second cavity region, by inserting the metallic leadframe between the first casting mold region and the second casting mold region, by bringing the first casting mold region and second casting mold region together such that the first cavity region and the second cavity region form a cavity between the first casting mold region and the second casting mold region for receiving the metallic leadframe such that a first contact region provided in the first cavity region bears against a second contact region provided in the second cavity region, and by filling the cavity with a plastic molding compound; and
inserting the integrated circuit into a test mount such that at least one centering portion formed on the plastic package bears against a centering stop in the test mount.
